(19) United States
(12) Patent Application Publication
(10) Pub. No.: US 2014/0091420 A1
(43) Pub. Date: Apr. 3, 2014

(54) METHOD OF MONOLITHICALLY INTEGRATED OPTOELECTRICS

(71) Applicant: Justin PAYNE, San Jose, CA (US)

(72) Inventor: Justin PAYNE, San Jose, CA (US)

(21) Appl. No.: 14/043,698

(22) Filed: Oct. 1, 2013

Related U.S. Application Data
(60) Provisional application No. 61/708,601, filed on Oct. 1, 2012.

(51) Int. Cl. H01L 27/144

(52) U.S. Cl. CPC H01L 27/144
USPC 257/443

(57) ABSTRACT

A monolithically integrated sensor is disclosed in the form of light detector(s), visible light emitter(s) and associated control circuit(s) monolithically integrated on a single silicon microchip. The detector structures consist of p-i-n photodiode structures, both diffused into and deposited on the surface of the silicon substrate. The emitter structures consist of III-V compound semiconductor hetero-epitaxial layers deposited on the surface of the silicon substrate. The control circuits are fabricated using traditional CMOS high volume manufacturing techniques. The sensor assembly is designed to be processed in a traditional CMOS wafer fab. The sensor assembly is further designed to be packaged at the wafer level.

### CROSS-REFERENCES TO RELATED APPLICATIONS

The present invention claims priority to and is a non-provisional of U.S. Provisional Application No. 61/708,601 filed Oct. 1, 2012, which is incorporated by reference herein for all purposes.

### FIELD OF THE INVENTION

The described invention relates generally to the field of Silicon Integrated Optoelectronics. More specifically, the described invention relates to Ambient Light Sensing, Solid State Lighting (SSL), Color Sensing, Proximity Sensing and Motion Detection.

### BACKGROUND OF THE INVENTION

This patent is related to a Proximity, Ambient Light and RGB Color sensor integrated on a single silicon chip.

Proximity Sensors, Ambient Light Sensors and RGB Color sensors are commonly employed in a range of consumer and industrial applications, particularly in mobile handset devices as well as in Solid State Lighting (SSL). Such sensors enable intelligent management of such items as adjusting the brightness of display screens, user interfaces and lighting luminaires, as well as “locking” and “unlocking” of touch sensitive display screens, to name two common application examples.

Existing sensor solutions consist of one of two general categories:
1) Separate discrete sensors, emitters and control circuit components. In this case each component is encased in an individual semiconductor package. These discrete components are mounted to a printed circuit board to form the final desired sensor combination.
2) Separate discrete sensors, emitters and control circuit components that are integrated into a single semiconductor package as a multi-chip module.

In both of these cases the minimum size of the sensor assembly is limited by the design rules for PCB layout and multi-chip package wire bonding. These packaging layout limitations result in a final sensor assembly that is several times larger in area than the total sum of silicon area of the individual components. One of the objects of this invention is to enable a significant reduction in the size of the final packaged sensor assembly, while increasing the number of sensor elements, and thus the breadth of functionality, included in the final assembly.

Also in both of the existing cases the minimum cost of the fabricated sensor assembly is limited by several factors: A separate silicon wafer must be processed for each sensor element, emitter element and circuit element (ASIC) that is included in the assembly. This reduces the economy of scale that drives wafer costs in high volume manufacturing, increasing the manufacturing cost. Packaging complexity increases with each additional element. For the case of the multi-chip module, packaging cost is directly related to the number of wire bonds required to interconnect all of the desired elements, as well as by the accuracy for placement and alignment of the various elements. Sensors and emitters must be able to communicate with the outside world, necessitating the implementation of multiple “windows” of materials with customized dielectric properties into each processed package. Each of these factors serves to set a baseline cost for a sensor assembly. Each of these factors also drives increased packaging cost with each additional sensor and circuit element that is added to the module.

Another object of the present invention is to dramatically reduce the packaging costs associated with the manufacturing of sensor assemblies, and to enable the integration of larger numbers of sensor and circuit elements with minimal packaging cost impact. In addition to cost savings, new functionality is possible with the present invention. Examples include easy control of LED based lighting systems where light color as well as light intensity can be adjusted with a single chip solution, as well as precise detectors with fast response circuits integrated on a single chip.

### SUMMARY OF THE INVENTION

This patent discloses a combination of Proximity sensor, Ambient Light sensor, Light emitter Color sensor and associated control ASIC integrated on a single silicon chip. This “multiple-in-1” sensor assembly is intended for use in any consumer or industrial application requiring proximity and light sensing. The disclosed invention is of particular use in mobile handsets and tablet computers as well as in SSL. Proximity sensing is used to lock and unlock the touch sensitive keypad and to turn off the display when the user holds the handset close to their ear to take a telephone call. Ambient light and color sensing are used to adjust the brightness of a display screen or a lighting luminaire in response to the light level in the user environment.

In the most general case the disclosed invention is formed from a single silicon substrate. The surface of this substrate is divided into several regions based upon the desired functionality: one region for each emitter structure, one region for each detector structure, and one region for each ASIC structure.

The emitter structures are composed of deposited hetero-epitaxial thin films of III-V compound semiconductors that form a p-n junction. One specific example of such a suitable compound semiconductor is an alloy of GaN or related III-N compounds. The emitter may additionally have a Distributed Bragg Reflector (DBR) fabricated as part of the bottom surface to increase light emission efficiency. Said emitters are encapsulated in a suitable dielectric compound such as SiO₂ or SiON, as two specific examples, to optimize their performance and isolate them from the surrounding environment.

The detector structures consist of three types. The first detector structure type is a set of diffused dopants in the silicon substrate that form a p-i-n photodiode structure. The second detector structure type is a set of deposited amorphous, poly-crystalline or epitaxial Si layers that form a p-i-n photodiode structure. Said p-i-n diodes will have their dopant concentrations and electrode structures arranged in a manner that suits the particular application for their intended use. They may be operated in either photovoltaic mode or depletion mode, again based upon the specific application. Said photodiodes are encapsulated by a suitable dielectric material, with SiO₂ and SiON as specific examples, to optimize their functionality and isolate them from the surrounding environment. The third detector structure is based on the same III-N compounds as used in the emitter. These III-N compounds allow for the fabrication of detectors which are wavelength selective, enabling a range of new applications that are not possible with a purely Si-based technology, such as solar blind UV detectors or flame/fire detectors.

The ASIC structures are composed of circuit elements (transistors, diodes, resistors, capacitors . . . ) fabricated using traditional CMOS processing based upon any of the available design rules (i.e. 250 nm, 180 nm, 130 nm, 90 nm, 65 nm . . . ). One or more levels of the metallization employed in the fabrication of the ASIC are employed to interconnect the ASIC with the detector and emitter structures in the manner required to realize final sensor assembly operation and functionality. The ASIC structure contains bond pad metallization to connect the final packaged sensor assembly to the “outside world” via wire bonds.

All sensor, emitter and ASIC circuit structures are aligned and positioned relative to each other as desired by the choice of mask layout. Such layout techniques enable positioning and alignment with nanometer scale accuracy.

All optically active elements are optically isolated from each other by a border of suitable “optically black” thin film dielectric material or a combination of such materials, with SiON, SiN, TiN and amorphous carbon (a-C) as four examples of suitable materials.

The resultant single chip module is packaged at the wafer level using any of several techniques. A suitably patterned dielectric wafer with suitable surface preparation may be bonded to the sensor/ASIC array wafer using a glass frit process, eutectic bonding process, thermo-compression bonding or adhesive bonding. Further, depending upon the application the sensor/ASIC array may be “packaged” in-fab by encapsulation with a layer(s) of a suitable dielectric material(s).

### BRIEF DESCRIPTION OF THE DRAWINGS

FIG. 1 is a top down view of a fully processed sensor chip as it appears after wafer dicing. The particular sensor assembly shown is comprised of a silicon substrate 1 and a glass cover wafer 3, and contains an ASIC 4; a diffused p-i-n photodiode 5, a deposited a-Si p-i-n photodiode 6 and a GaN based light emitter 7.

FIG. 2 is a cross section view of the same sensor chip taken through line 2-2. This figure illustrates the z-dimensions of the ASIC 4, c-Si photodiode 5, a-Si photodiode 6 and emitter structures 7; the relative clearance between the device top surface and the cover wafer patterned surface 10, the cover wafer to device wafer bonded region 9 and Device Wafer Bond Pad dice-out 11 dimensions.

FIG. 3 is a top down view of a fully processed sensor chip as it appears after wafer dicing. The particular sensor assembly shown is comprised of a silicon substrate 1 and a glass cover wafer 3, and contains an ASIC 4; a diffused p-i-n photodiode 5, a deposited a-Si p-i-n photodiode 6 fabricated directly above the ASIC 4 and a GaN based light emitter 7.

FIG. 4 is a cross section view of the same sensor chip taken through line 32-32. This figure illustrates the z-dimensions and lateral placement of the ASIC 4, c-Si photodiode 5, a-Si photodiode 6 and emitter structures 7; the relative clearance between the device top surface and the cover wafer patterned surface 10, the cover wafer to device wafer bonded region 9 and Device Wafer Bond Pad dice-out 11 dimensions.

FIG. 5 is a top down view of a fully processed sensor chip as it appears after wafer dicing. The particular sensor assembly shown is comprised of a silicon substrate 1 and a glass cover wafer 3, and contains an ASIC 4; a diffused p-i-n photodiode 5, a deposited a-Si p-i-n photodiode 6 fabricated directly above the diffused photodiode 5 and a GaN based light emitter 7.

FIG. 6 is a cross section view of the same sensor chip taken through line 52-52. This figure illustrates the z-dimensions and lateral placement of the ASIC 4, c-Si photodiode 5, a-Si photodiode 6 and emitter structures 7; the relative clearance between the device top surface and the cover wafer patterned surface 10, the cover wafer to device wafer bonded region 9 and Device Wafer Bond Pad dice-out 11 dimensions.

FIG. 7 is a top down view of a fully processed sensor chip as it appears after wafer dicing. The particular sensor assembly shown is comprised of a silicon substrate 1 and a glass cover wafer 3, and contains an ASIC 4; a MEMS Micro-bolometer 12, a deposited a-Si p-i-n photodiode 6 and a GaN based light emitter 7.

FIG. 8 is a cross section view of the same sensor chip taken through line 72-72. This figure illustrates the z-dimensions of the ASIC 4, MEMS Micro-bolometer 12, a-Si photodiode 6 and emitter structures 7; the relative clearance between the device top surface and the cover wafer patterned surface 10, the cover wafer to device wafer bonded region 9 and Device Wafer Bond Pad dice-out 11 dimensions.

### DETAILED DESCRIPTION OF EXAMPLES

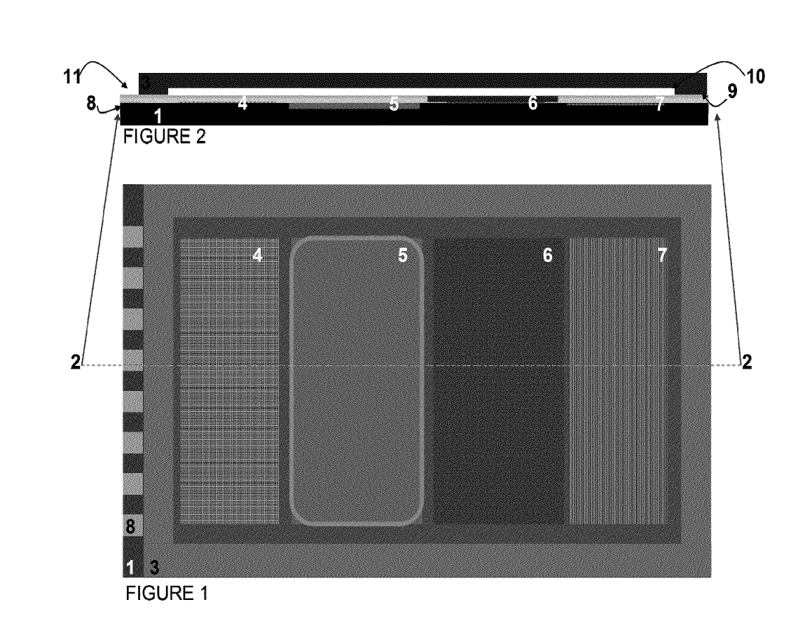

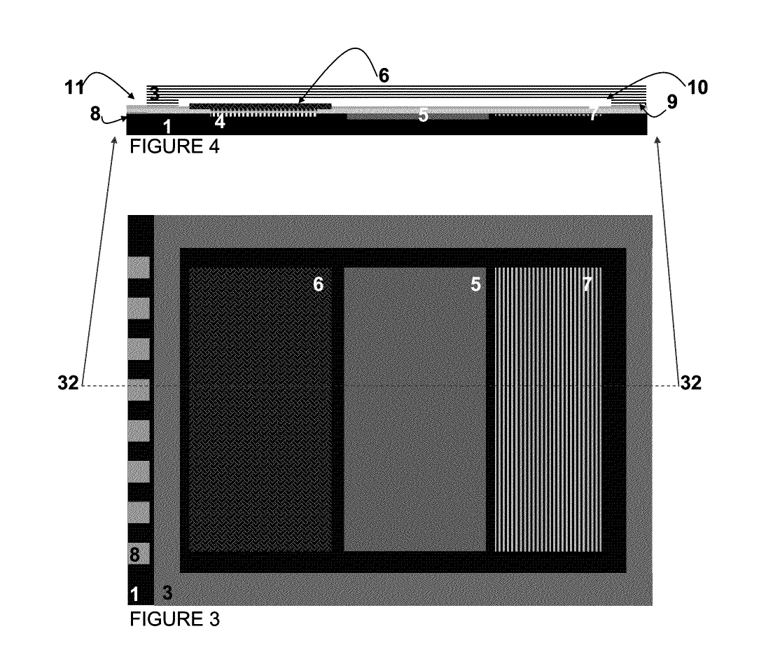

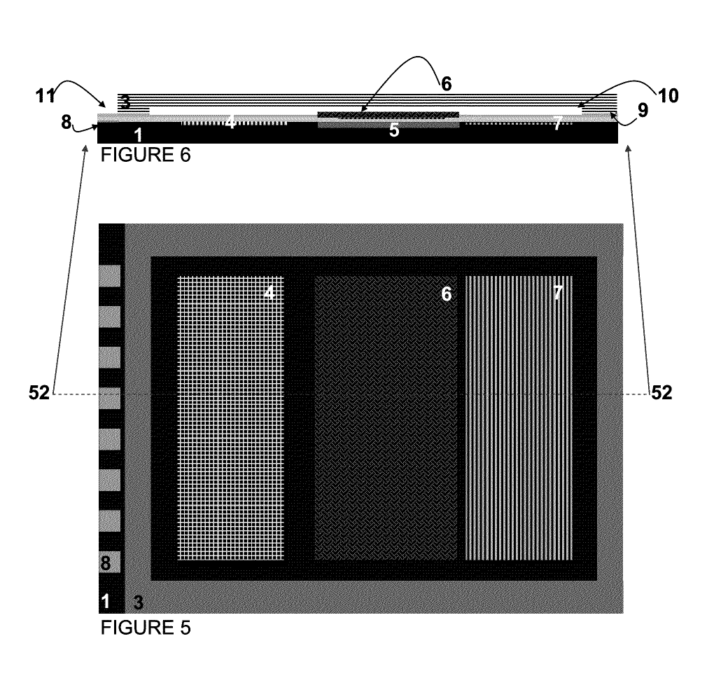

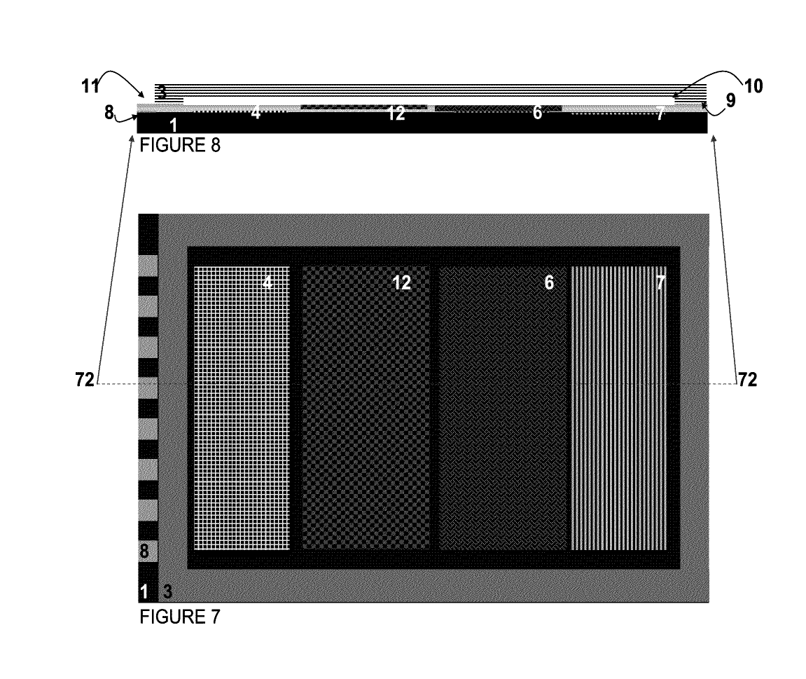

Referring to FIG. 1, the integrated sensor array and CMOS ASIC 1 is shown along with the key functional regions: CMOS circuitry 4, c-Si p-i-n photodiode 5, a-Si p-i-n photodiode 6 and III-V emitter 7. The silicon sensor chip is covered by a SiO₂ cover glass 3 that has been patterned to provide clearance for the device elements as appropriate and bonded to silicon substrate

A cross section of the completed sensor and circuitry array is shown in FIG. 2. The cross section illustrates the aforementioned device element clearance space 10 as is patterned into the cover glass 3, as well as the bonding interface 9 of cover glass 3 to the silicon based sensor array 1. The cover glass is patterned to provide a clear-out 11 for the Bond Pads on the silicon sensor chip to facilitate connection to external circuitry as appropriate. The clear-out 11 is physically created during the wafer dicing process, where the chip is cut out and removed from the bonded wafer assembly.

In one or more examples, the following claims are included.

1) A sensor array comprising a plurality of optoelectronic components integrated on to a single silicon substrate.

2) The sensor array in claim (1) comprising a plurality of optoelectronic components as well as CMOS circuits integrated on to a single silicon substrate.

3) The sensor array in claim (1) comprising a Proximity Sensor, Ambient Light Sensor, Color Sensor, UV Sensor, IR Sensor and Light Emitter.

4) The sensor array in claim (1) comprising a Proximity Sensor, Ambient Light Sensor and Light Emitter.

5) The sensor array in claim (1) comprising a Proximity Sensor, Ambient Light Sensor, Color Sensor, RGB Color Sensor, UV Sensor, IR Sensor, Light Emitter.

6) The sensor array in claim (1) comprising a Proximity Sensor, Ambient Light Sensor, Color Sensor, UV Sensor, IR Sensor, Light Emitter.

7) The sensor array in claim (1) comprising a Proximity Sensor, Ambient Light Sensor, Light Emitter.

8) The sensor array in claim (1) comprising a Proximity Sensor, Light Emitter.

9) The sensor array in claim (1) comprising an Ambient Light Sensor, Light Emitter.

10) The sensor array in claim (1) comprising a Color Sensor, Light Emitter.

11) The sensor array in claim (1) comprising an IR Sensor, Light Emitter.

12) The sensor array in claim (1) comprising a UV Sensor, Light Emitter.

13) The sensor array in claim (1) comprising an RGB Color Sensor, Light Emitter.

14) The sensor array in claim (1) comprising a Proximity Sensor, IR Sensor, Light Emitter.

15) The sensor array in claim (1) comprising a Proximity Sensor, UV Sensor, Light Emitter.

16) The sensor array in claim (1) comprising a Proximity Sensor, Color Sensor, Light Emitter.

17) The sensor array in claim (1) comprising a Proximity Sensor, RGB Color Sensor, Light Emitter.

18) The sensor array in claim (1) comprising an Ambient Light Sensor, IR Sensor, Light Emitter.

19) The sensor array in claim (1) comprising an Ambient Light Sensor, UV Sensor, Light Emitter.

20) The sensor array in claim (1) comprising an Ambient Light Sensor, Color Sensor, Light Emitter.

21) The sensor array in claim (1) comprising an Ambient Light Sensor, RGB Color Sensor, Light Emitter.

22) The sensor array in claim (1) comprising an IR Sensor, UV Sensor, Color Sensor, RGB Color Sensor, Light Emitter.

23) The sensor array in claim (1) comprising an IR Sensor, Color Sensor, RGB Color Sensor, Light Emitter.

24) The sensor array in claim (1) comprising an IR Sensor, UV Sensor, RGB Color Sensor, Light Emitter.

25) The sensor array in claim (1) comprising an IR Sensor, UV Sensor, Color Sensor, Light Emitter.

26) The sensor array in claim (1) comprising an UV Sensor, Color Sensor, RGB Color Sensor, Light Emitter.

27) The sensor array in claim (1) comprising an UV Sensor, RGB Color Sensor, Light Emitter.

28) The sensor array in claim (1) comprising an UV Sensor, Color Sensor, Light Emitter.

29) The sensor array in claim (1) comprising an IR Sensor, UV Sensor, Light Emitter.

30) The sensor array in claim (1) comprising an IR Sensor, Color Sensor, Light Emitter.

31) The sensor array in claim (1) comprising an IR Sensor, RGB Color Sensor, Light Emitter.

32) The sensor array in claim (1) comprising a Color Sensor, RGB Color Sensor, Light Emitter.

33) The sensor array in claim (1) comprising a Proximity Sensor, Ambient Light Sensor, Color Sensor, Light Emitter.

34) The sensor array in claim (1) comprising a Proximity Sensor, Ambient Light Sensor, RGB Sensor, Light Emitter.

35) The sensor array in claim (1) comprising a Proximity Sensor, Ambient Light Sensor, IR Sensor, Light Emitter.

36) The sensor array in claim (1) comprising a Proximity Sensor, Ambient Light Sensor, UV Sensor, Light Emitter.

37) The sensor array in claim (1) comprising a Proximity Sensor, Color Sensor, RGB Sensor, Light Emitter.

38) The sensor array in claim (1) comprising a Proximity Sensor, Color Sensor, IR Sensor, Light Emitter.

39) The sensor array in claim (1) comprising a Proximity Sensor, Color Sensor, UV Sensor, Light Emitter.

40) The sensor array in claim (1) comprising a Proximity Sensor, RGB Sensor, IR Sensor, Light Emitter.

41) The sensor array in claim (1) comprising a Proximity Sensor, RGB Sensor, UV Sensor, Light Emitter.

42) The sensor array in claim (1) comprising a Proximity Sensor, IR Sensor, UV Sensor, Light Emitter.

43) The sensor array in claim (1) comprising a Ambient Light Sensor, Color Sensor, RGB Sensor, Light Emitter.

44) The sensor array in claim (1) comprising a Ambient Light Sensor, Color Sensor, IR Sensor, Light Emitter.

45) The sensor array in claim (1) comprising a Ambient Light Sensor, Color Sensor, UV Sensor, Light Emitter.

46) The sensor array in claim (1) comprising a Ambient Light Sensor, RGB Sensor, IR Sensor, Light Emitter.

47) The sensor array in claim (1) comprising a Ambient Light Sensor, RGB Sensor, UV Sensor, Light Emitter.

48) The sensor array in claim (1) comprising a Ambient Light Sensor, IR Sensor, UV Sensor, Light Emitter.

49) The sensor array in claim (1) comprising a Proximity Sensor, Color Sensor, UV Sensor, IR Sensor, Light Emitter.

50) The sensor array in claim (1) comprising a Proximity Sensor, Ambient Light Sensor, UV Sensor, IR Sensor, Light Emitter.

51) The sensor array in claim (1) comprising a Proximity Sensor, Ambient Light Sensor, Color Sensor, IR Sensor, Light Emitter.

52) The sensor array in claim (1) comprising a Proximity Sensor, Ambient Light Sensor, Color Sensor, UV Sensor, Light Emitter.

53) The sensor array in claim (1) comprising a Proximity Sensor, Color Sensor, RGB Color Sensor, UV Sensor, IR Sensor, Light Emitter.

54) The sensor array in claim (1) comprising a Proximity Sensor, Ambient Light Sensor, UV Sensor, IR Sensor, RGB Color Sensor, Light Emitter.

55) The sensor array in claim (1) comprising a Proximity Sensor, Ambient Light Sensor, Color Sensor, RGB Color Sensor, IR Sensor, Light Emitter.

56) The sensor array in claim (1) comprising a Proximity Sensor, Ambient Light Sensor, Color Sensor, RGB Color Sensor, UV Sensor, Light Emitter.

57) The sensor array in claim (1) comprising a Proximity Sensor, RGB Color Sensor, UV Sensor, IR Sensor, Light Emitter.

58) The sensor array in claim (1) comprising a Proximity Sensor, Ambient Light Sensor, UV Sensor, IR Sensor, Light Emitter.

59) The sensor array in claim (1) comprising a Proximity Sensor, Ambient Light Sensor, RGB Sensor, IR Sensor, Light Emitter.

60) The sensor array in claim (1) comprising a Proximity Sensor, Ambient Light Sensor, Color Sensor, RGB Sensor, Light Emitter.

61) The sensor array in claim (1) comprising a Proximity Sensor, Color Sensor, RGB Sensor, IR Sensor, Light Emitter.

62) The sensor array in claim (1) comprising a Proximity Sensor, Color Sensor, IR Sensor, UV Sensor, Light Emitter.

63) The sensor array in claim (1) comprising a Proximity Sensor, Ambient Light Sensor, Color Sensor, IR Sensor, Light Emitter.

64) The sensor array in claim (1) comprising a Proximity Sensor, Color Sensor, RGB Color Sensor, UV Sensor, Light Emitter.

65) The sensor array in claim (1) comprising a Proximity Sensor, Ambient Light Sensor, RGB Color Sensor, UV Sensor, Light Emitter.

66) The sensor array in claim (1) comprising a Proximity Sensor, Ambient Light Sensor, Color Sensor, UV Sensor, Light Emitter.

67) The sensor array in claim (1) comprising an Ambient Light Sensor, Color Sensor, RGB Color Sensor, UV Sensor, Light Emitter.

68) The sensor array in claim (1) comprising an Ambient Light Sensor, Color Sensor, RGB Color Sensor, IR Sensor, Light Emitter.

69) The sensor array in claim (1) comprising an Ambient Light Sensor, Color Sensor, UV Sensor, IR Sensor, Light Emitter.

70) The sensor array in claim (1) comprising an Ambient Light Sensor, RGB Color Sensor, UV Sensor, IR Sensor, Light Emitter.

71) The sensor array in claim (1) comprising an Ambient Light Sensor, Color Sensor, RGB Color Sensor, UV Sensor, IR Sensor, Light Emitter.

72) The sensor array in claim (1) comprising a Proximity Sensor, Ambient Light Sensor, Color Sensor, UV Sensor, IR Sensor, Light Emitter.

73) The sensor and circuit array in claim (2) having the circuit elements comprised of an emitter driver, sensor control circuit and/or communication I/O circuit or circuits.

74) The combination sensor in claim (1) having the optoelectronic component chip and control circuit chip integrated into a single semiconductor package as a unit.

75) The sensor array in claim (2) having the integrated optoelectronic and CMOS circuit chip packaged using traditional semiconductor techniques after wafer dicing.

76) The sensor array in claim (2) having the integrated optoelectronic and CMOS circuit chip packaged at the wafer level before wafer dicing.

77) The combination sensor in claim (1) having the optoelectronic component chip packaged at the wafer level and subsequently co-packaged with the control circuit chip to form an integrated single unit.

78) The packaged sensor in claim (76) where the wafer level packaging comprises a glass frit bonded cover wafer.

79) The packaged sensor in claim (76) where the wafer level packaging comprises a eutectic metallic bonded cover wafer.

80) The packaged sensor in claim (76) where the wafer level packaging comprises a polymeric adhesive bonded cover wafer.

81) The packaged sensor and bonded wafer assembly in claim (80) where the polymeric adhesive bond is comprised of a glass cover wafer and BCB polymeric material.

82) The packaged sensor in claim (77) where the wafer level packaging comprises a glass frit bonded cover wafer.

83) The packaged sensor in claim (77) where the wafer level packaging comprises a eutectic metallic bonded cover wafer.

84) The packaged sensor in claim (77) where the wafer level packaging comprises a polymeric adhesive bonded cover wafer.

85) The packaged sensor and bonded wafer assembly in claim (84) where the polymeric adhesive bond is comprised of a glass cover wafer and BCB polymeric material.

86) The sensor array in claim (1) comprising a MEMS Micro-bolometer, Ambient Light Sensor and Light Emitter.

87) The sensor array in claim (1) comprising a MEMS Micro-bolometer and Ambient Light Sensor.

88) The sensor array in claim (1) comprising a optically isolated switch, with an Opto-TRIAC as one common example.

89) The invention in claim (1) comprising optical interconnects integrated on the silicon substrate.

90) The invention in claim (1) where the substrate is comprised of a SOI wafer.

91) The invention in claim (90) where at least one of the optoelectronic components is fabricated in the SOI layer of the SOI wafer.

92) The invention in claim (90) where at least one of the optoelectronic components is fabricated in the bulk silicon layer of the SOI wafer.

93) The invention in claim (90) where at least one of the optoelectronic components is fabricated on the SOI layer of the SOI wafer.

94) The invention in claim (90) where at least one of the optoelectronic components is fabricated on the bulk silicon layer of the SOI wafer.

95) The invention in claim (1) consisting of an integrated light emitter, light detector(s) co-packaged with a control ASIC for use in intelligent solid state lighting.

96) The invention in claim (2) consisting of an integrated light emitter, light detector(s) and control ASIC for use in intelligent solid state lighting.

97) The invention in claim (1) consisting of an integrated light emitter, light detector(s) co-packaged with a control ASIC for use in a lighting LAN communication device.

98) The invention in claim (2) consisting of an integrated light emitter, light detector(s) and control ASIC for use in a lighting LAN communication device.

What is claimed is:

1. A sensor array comprising a plurality of optoelectronic components integrated on to a single silicon substrate.
